(19) United States
(12) Patent Application Publication
(10) Pub. No.: US 2025/0163580 A1
(43) Pub. Date: May 22, 2025

(54) A SUBSTRATE PROCESSING APPARATUS AND A METHOD

(71) Applicant: Picosun Oy, Espoo (FI)

(72) Inventors: Antti KUITUNEN, Espoo (FI); Tom BLOMBERG, Espoo (FI); Jani KIVIOJA, Espoo (FI); Juho POUTIAINEN, Espoo (FI); Heikki ALAKOSKI, Espoo (FI)

(21) Appl. No.: 18/685,933

(22) PCT Filed: Sep. 12, 2022
(86) PCT No.: PCT/FI2022/050612

§ 371 Date: Feb. 23, 2024

(30) Foreign Application Priority Data
Sep. 14, 2021 (FI) 20215968

(51) Int. Cl. C23C 16/455

(52) U.S. Cl. CPC C23C 16/45587; C23C 16/45536

(57) ABSTRACT

A substrate processing apparatus (100), comprising a reaction chamber (20) for processing at least one substrate, and a deformable in-feed assembly (85) comprising an upper (70) and a lower (80) portion movable with respect to each other, the deformable in-feed assembly (85) being configured to deform between a vertically extended state facilitating a reactant flow towards the reaction chamber (20), and a vertically retracted state allowing substrate loading, and a resilient tubular conduit (150) coupled to the upper portion (70) of the deformable in-feed assembly (85).

### TECHNICAL FIELD

The present invention generally relates to substrate processing reactors with a plasma source. More particularly, but not exclusively, the invention relates to deposition reactors in which material is deposited on surfaces by sequential self-saturating surface reactions, or to etching reactors in which material is removed from surfaces by sequential self-saturating surface reactions.

### BACKGROUND

This section illustrates useful background information without admission of any technique described herein representative of the state of the art.

In chemical deposition and etching methods, such as atomic layer deposition (ALD) and atomic layer etching (ALE), plasma can be used to provide required additional energy for surface reactions. While ALD and ALE reactors have existed for many decades, plasma-enhanced reactors represent a younger technology. There is thus an ongoing need to develop improved plasma-enhanced ALD (PEALD) and plasma-enhanced ALE (PEALE) reactors or at least to provide alternatives to existing solutions.

Typically, a substrate processing reactor must comprise moving components in order to enable at least substrate loading and unloading, as well as adjustment of the position of the parts. However, moving components inside a reactor are associated with certain disadvantages, a common problem being unnecessary contact between the reactor components which can lead to generation of unwanted particles inside a reactor, which particles may end up on the substrate itself resulting in contamination. The said problem often manifests itself as challenges in moving the reactor components between loading and processing positions of a substrate. Therefore, there is an ongoing need for improved solutions to reduce unwanted particles in substrate processing reactors, particularly with a plasma source.

### SUMMARY

It is an object of certain embodiments of the invention to provide an improved substrate processing apparatus or at least to provide an alternative solution to existing technology.

According to a first example aspect is provided a substrate processing apparatus, comprising:
a reaction chamber for processing at least one substrate;
a deformable in-feed assembly comprising an upper and a lower portion movable with respect to each other, the deformable in-feed assembly being configured to deform between a vertically extended state facilitating a reactant flow towards the reaction chamber, and a vertically retracted state allowing substrate loading; and
a resilient tubular conduit coupled to the upper portion of the deformable in-feed assembly.

In certain embodiments, the upper portion of the deformable in-feed assembly is a first portion, and the lower portion of the deformable in-feed assembly is a second portion, wherein the first portion resides closer to the reaction chamber and the second portion resides farther from the reaction chamber when the deformable in-feed assembly is in its vertically extended state. In certain embodiments, the deformable in-feed assembly is configured to close or seal the reaction chamber from the top (in the vertically extended state). In certain embodiments, the deformable in-feed assembly is supported by the resilient tubular conduit from the top. In certain embodiments, the resilient tubular conduit is fixedly attached to the upper portion of the deformable in-feed assembly.

In certain embodiments, the resilient tubular conduit is configured to provide the deformable in-feed assembly with the reactant flow. In certain embodiments, the resilient tubular conduit provides a conduit through which the reactant flow is provided into the upper portion of the deformable in-feed assembly. In certain embodiments, the resilient tubular conduit is configured to provide reactants as a top to bottom flow into the upper portion of the deformable in-feed assembly. In certain embodiments, the upper and the lower portion of the deformable in-feed assembly are configured to lead or facilitate movement of the reactant flow as a top to bottom flow towards the reaction chamber. In certain embodiments, the apparatus is configured to deform the deformable in-feed assembly into a vertically retracted state to allow substrate unloading.

In certain embodiments, the resilient tubular conduit is coupled between the upper portion of the deformable in-feed assembly and a fixed element of the apparatus. In certain embodiments, the fixed element is an outer chamber. In certain embodiments, the resilient tubular conduit is coupled between an outer chamber at least partly surrounding the reaction chamber and the upper portion of the deformable in-feed assembly. In certain embodiments, the resilient tubular conduit is coupled between an outer chamber lid and the upper portion of the deformable in-feed assembly, wherein the outer chamber at least partly surrounds the reaction chamber. In certain embodiments, the resilient tubular conduit is coupled between the upper portion of the deformable in-feed assembly and a sealing component, which is coupled to the fixed element of the apparatus with a fixed position.

In certain embodiments, the resilient tubular conduit is arranged in a fixed position with respect to its attachment point to the fixed element of the apparatus. In certain embodiments, the resilient tubular conduit is arranged in a fixed position with respect to its attachment point to the outer chamber. In certain embodiments, the deformable in-feed assembly is coupled to the outer chamber via the resilient tubular conduit to provide the reactant flow into a volume within the reaction chamber

In certain embodiments, the positions of all the portions of the deformable in-feed assembly are adjustable.

In certain embodiments, the substrate processing apparatus is a plasma-enhanced atomic layer deposition apparatus, a PEALD reactor. In certain embodiments, the substrate processing apparatus is an atomic layer deposition apparatus, an ALD reactor. In certain other embodiments, the substrate processing apparatus is a plasma-enhanced atomic layer etching apparatus, a PEALE reactor. In certain embodiments, the substrate processing apparatus is an atomic layer etching apparatus, an ALE reactor. In certain embodiments, the apparatus comprises a plasma source on the top side of the reaction chamber. In certain embodiments, the deposition apparatus comprises a plasma source on the top side of the outer chamber. In certain embodiments, the plasma source is an inductively coupled plasma source. In certain embodiments, the plasma source is configured to produce radicals used as reactants in the reaction chamber.

In certain embodiments, the apparatus provides a top to bottom flow route for the reactant flow from the plasma source, through the resilient tubular conduit into the deformable in-feed assembly, and into the reaction chamber. In certain embodiments the reactants are configured to be exhausted from the reaction chamber through an outlet at the bottom of the reaction chamber.

In certain embodiments, a reactant flow is comprised of gasses containing reactants. In certain embodiments, reactants comprise fluid reactants, gaseous reactants, and/or plasma reactants. In certain embodiments, the reactant flow is configured to flow within the conduit provided by the resilient tubular conduit. In certain embodiments, the reactants comprising excited species generated in the plasma source are configured to flow through an inner conduit of the resilient tubular conduit towards the reaction chamber. In certain embodiments, the reactants, comprising the excited species, are configured to flow through the deformable in-feed assembly to the substrate(s) residing in the reaction chamber to generate surface reactions.

In certain embodiments, an intermediate space is formed between the reaction chamber and the outer chamber at least partly surrounding the reaction chamber. In certain embodiments the outer chamber surrounds the reaction chamber entirely. In certain embodiments the intermediate space formed between the reaction chamber and the outer chamber surrounds the reaction chamber entirely. By “entirely” in this respect means, the reaction chamber is considered to be surrounded entirely by the outer chamber and/or the intermediate space, as the reaction chamber wherein the substrates are processed, is surrounded by the outer chamber, excluding the positions of any inlets and/or outlets to/from the reaction chamber. In certain embodiments, the resilient tubular conduit and the deformable in-feed assembly are arranged within a same space. In certain embodiments, the resilient tubular conduit and the deformable in-feed assembly are arranged within the intermediate space inside the outer chamber.

In certain embodiments, the resilient tubular conduit is coupled to the upper portion of the in-feed assembly, for example, via a flange.

In certain embodiments, the resilient tubular conduit is configured to generate mechanical force to the deformable in-feed assembly with its internally stored mechanical potential energy. In certain embodiments, the resilient tubular conduit is configured to generate mechanical force to the deformable in-feed assembly with its internally stored elastic energy. In certain embodiments, the resilient tubular conduit is configured to generate mechanical force to the upper portion of the deformable in-feed assembly. In certain embodiments, the resilient tubular conduit is configured to generate mechanical force to the upper portion and the lower portion of the deformable in-feed assembly.

In certain embodiments, the resilient tubular conduit is configured to generate mechanical force to the deformable in-feed assembly, to stabilize the upper portion of the deformable in-feed assembly. In certain embodiments, the resilient tubular conduit is configured to adjust a position of the upper portion of the deformable in-feed assembly. In certain embodiments, the resilient tubular conduit is configured to stabilize and adjust the position of the upper portion of the deformable in-feed assembly by generating mechanical force to the deformable in-feed assembly.

In certain embodiments, the resilient tubular conduit is an elastic object configured to store mechanical potential energy. In certain embodiments, the resilient tubular conduit is configured to be pre-tensioned. In certain embodiments, a pre-tensioned resilient tubular conduit is coupled to the upper portion of the deformable in-feed assembly, configured to provide the deformable in-feed assembly with the reactant flow.

In certain embodiments, the resilient tubular conduit is configured to adjust a vertical and/or a horizontal and/or an angular position of the upper portion of the deformable in-feed assembly. In certain embodiments, the resilient tubular conduit is configured to adjust the position of the upper portion of the deformable in-feed assembly by pulling or retracting the upper portion towards the resilient tubular conduit and/or in line with the vertical centre axis of the lower portion of the deformable in-feed assembly.

In certain embodiments, the resilient tubular conduit is configured to pull or retract the upper portion of the deformable in-feed assembly away from the reaction chamber. In certain embodiments, the resilient tubular conduit is configured to pull or retract the upper and the lower portion of the deformable in-feed assembly away from the reaction chamber.

In certain embodiments, the mechanical force generated by the resilient tubular conduit is configured to adjust the position of the upper portion of the deformable in-feed assembly by pulling or retracting the upper portion towards the resilient tubular conduit and/or in line with the vertical centre axis of the lower portion of the deformable in-feed assembly. In certain embodiments, the mechanical force generated by the resilient tubular conduit is not configured to adjust the position of the lower portion of the deformable in-feed assembly. In certain embodiments, the mechanical force generated by the resilient tubular conduit is not enough to adjust the position of the lower portion of the deformable in-feed assembly.

In certain embodiments, the mechanical force generated by the resilient tubular conduit is configured to co-centre the upper portion with the lower portion of the deformable in-feed assembly, thereby preventing unwanted contact between the upper and lower portions of the deformable in-feed assembly. By unwanted contact in this respect is meant the type of contact between the upper and lower portion of the deformable in-feed assembly that can lead to unwanted particle generation which would take place as a result of the said contact between the parts of the apparatus.

In certain embodiments, the mechanical energy within the resilient tubular conduit is configured to co-centre the upper portion with the lower portion of the deformable in-feed assembly during the deformation of the deformable in-feed assembly and in the vertically extended, and/or retracted state. In certain embodiments, the co-centering means, the upper and the lower portions of the deformable in-feed assembly are aligned with the same vertical centre axis thereby preventing unwanted contact between the upper and lower portions of the deformable in-feed assembly. In certain embodiments, the resilient tubular conduit is configured to co-centre the upper portion with the lower portion of the deformable in-feed assembly during the deformation of the deformable in-feed assembly, thereby preventing unwanted contact between the outer surface of the upper portion and the inner surface of the lower portion of the deformable in-feed assembly.

In certain embodiments, the resilient tubular conduit is configured to stabilize the deformable in-feed assembly. In certain embodiments, the resilient tubular conduit is configured to stabilize the movement of the deformable in-feed assembly. In certain embodiments, stabilizing the movement of the deformable in-feed assembly reduces unwanted particle generation. In certain embodiments, the resilient tubular conduit is configured to prevent vibration and unwanted particle generation of the deformable in-feed assembly primarily while it is being moved. In certain embodiments, the resilient tubular conduit is configured to prevent vibration and unwanted particle generation of the deformable in-feed assembly also while it is stationary.

In certain embodiments, the mechanical energy within the resilient tubular conduit is configured to pull or retract the upper portion of the deformable in-feed assembly upwards, away from the reaction chamber during the deformation of the deformable in-feed assembly and in the vertically extended, and/or retracted state.

In certain embodiments, the resilient tubular conduit is configured to be continuously stretched. In certain embodiments, the resilient tubular conduit is configured to be vertically stretched during the vertical deformation movement of the deformable in-feed assembly. In certain embodiments, the resilient tubular conduit is configured to be stretched under displacement of the lower portion of the deformable in-feed assembly in respect of the upper portion of the deformable in-feed assembly. In certain embodiments, the resilient tubular conduit is configured to stretch or compress under mechanical force generated by the deformable in-feed assembly. In certain embodiments, the resilient tubular conduit is configured to stretch or compress in the vertically extended state of the deformable in-feed assembly. In certain embodiments, the resilient tubular conduit is configured to stretch or compress under vertical movement of the vertically extended deformable in-feed assembly.

In certain embodiments, the resilient tubular conduit is configured to further stretch vertically when the deformable in-feed assembly in the vertically extended state is moved towards the reaction chamber. In certain embodiments, the resilient tubular conduit is configured to compress vertically when the deformable in-feed assembly in the vertically extended state is moved apart from the reaction chamber.

In certain embodiments, the resilient tubular conduit is configured to be resilient horizontally and/or vertically and/or angularly. In certain embodiments, the resilient tubular conduit is configured to be resilient in multiple axes.

In certain embodiments, the resilient tubular conduit is an elastic tubular vessel. In certain embodiments, the resilient tubular conduit is a bellows-shaped object. In certain embodiments, the resilient tubular conduit is a tubular metal bellows. In certain embodiments, the resilient tubular conduit is a tubular spring-shaped object. In certain embodiments, the resilient tubular conduit is comprised of nickel-based alloy, such as AISI 304, AISI 304L, AISI 316 or AISI 316L, and/or Inconel and/or Titanium. In certain embodiments, the resilient tubular conduit is comprised of a material with a similar thermal expansion coefficient as the materials of the surrounding components have.

In certain embodiments, the resilient tubular conduit is configured to deform when mechanical force is applied to it. In certain embodiments, the resilient tubular conduit is configured to be compressed or to retract and/or to be stretched when mechanical force is applied to it. In certain embodiments, the resilient tubular conduit is configured to return to its starting position when the applied force is released or removed.

In certain embodiments, thermal expansion or contraction does not cause significant relative movement between the components making up the resilient tubular conduit. In certain embodiments, the resilient tubular conduit is configured not to significantly deform in response to temperature changes. In certain embodiments, the resilient tubular conduit is configured not to significantly deform in response to pressure changes in the surrounding space.

In certain embodiments, the resilient tubular conduit is configured to form a sealed barrier between its inner conduit volume and the space surrounding the resilient tubular conduit from the outside, which is typically the intermediate space within the outer chamber. In certain embodiments, the resilient tubular conduit is configured to form a sealed connection with the upper portion of the deformable in-feed assembly and with the fixed element of the apparatus, such as the outer chamber. In certain embodiments, the resilient tubular conduit is configured to prevent leakage of reactants from the resilient tubular conduit into the surrounding space, such as the intermediate space within the outer chamber. In certain embodiments, the resilient tubular conduit is also configured to prevent leakage of gasses from the outside surrounding space into the inner volume of the resilient tubular conduit.

In certain embodiments, the resilient tubular conduit is configured to prevent leakage of the deformable in-feed assembly at a joint between the upper and the lower portion of the deformable in-feed assembly. In certain embodiments, the resilient tubular conduit is configured to prevent leakage of the deformable in-feed assembly also at distal ends of the deformable in-feed assembly, at joints coupled to other parts of the apparatus. In certain embodiments, the resilient tubular conduit is configured to deform to prevent leakage between portions or modules of the deformable in-feed assembly. In certain embodiments, the resilient tubular conduit is configured to deform to prevent leakage of the deformable in-feed assembly in the vertically extended state.

In certain embodiments, the lower portion of the deformable in-feed assembly is comprised of more than one portion.

In certain embodiments, the lower portion of the deformable in-feed assembly is configured to be sealed against the reaction chamber in the vertically extended state of the deformable in-feed assembly to provide the reaction chamber with the reactant flow. In certain embodiments, the vertically extended deformable in-feed assembly is configured to be positioned against the reaction chamber so as to form a reaction chamber volume, to provide the reaction chamber with the reactant flow for substrate processing. In certain embodiments, the lower portion of the deformable in-feed assembly is configured to adopt the said position against the reaction chamber which is a leak-tight position. In certain embodiments, a lower rim of the deformable in-feed assembly is configured to be sealed against an edge of an opening of the reaction chamber in the vertically extended state of the deformable in-feed assembly.

In certain embodiments, a surface-against-a-surface-seal is provided between the deformable in-feed assembly and the reaction chamber in the vertically extended state of the deformable in-feed assembly. In certain embodiments, the reaction chamber comprises a flange or a collar fitted against the lower portion of the deformable in-feed assembly in the vertically extended state. In certain embodiments, the deformable in-feed assembly is coupled to an in-feed assembly flange which is fitted against the reaction chamber flange in the vertically extended state of the deformable in-feed assembly.

In certain embodiments, the deformable in-feed assembly widens towards the reaction chamber. In certain embodiments, the deformable in-feed assembly widens towards the reaction chamber in the vertically extended state. In certain embodiments, the deformable in-feed assembly delimits a widening or expanding volume with its cylinder shaped upper and lower portions, the volume widening or expanding towards the reaction chamber.

In certain embodiments, the apparatus comprises a sealed interface between the lower portion and the upper portion of the deformable in-feed assembly in the vertically extended state of the deformable in-feed assembly. In certain embodiments, the said sealed interface is configured to prevent leakage of the deformable in-feed assembly.

In certain embodiments, a lower rim of the upper portion, and an upper rim of the lower portion of the deformable in-feed assembly comprise a horizontal collar, the said horizontal collar of the upper and lower portion overlapping with each other in the extended state of the deformable in-feed assembly. In certain embodiments, these overlapping collars form a hook-structure, allowing the overlapping collar of the lower portion to hang on, or be suspended from the collar of the upper portion. In certain embodiments, these overlapping collars are configured to prevent leakage of the vertically extended deformable in-feed assembly.

In certain embodiments, a seal is provided between the upper and lower portion of the deformable in-feed assembly, thereby preventing unwanted contact between the upper and lower portions and preventing leakage of the deformable in-feed assembly. In certain embodiments, the seal prevents leakage of gasses from the surrounding space into the volume inside the deformable in-feed assembly. In certain embodiments, the seal prevents reactant leakage from the deformable in-feed assembly into the surrounding space.

In certain embodiments, the portions of the deformable in-feed assembly are configured to nest inside each other in the vertically retracted state of the deformable in-feed assembly.

In certain embodiments, the lower portion of the deformable in-feed assembly is configured to slide over the upper portion of the deformable in-feed assembly. In certain embodiments, the upper portion of the deformable in-feed assembly is configured to nest inside the lower portion of the deformable in-feed assembly in the vertically retracted state of the in-feed assembly. In certain embodiments, the deformable in-feed assembly is formed of cylinders, truncated cones or ring-like members configured to slide and/or nest inside each other. In certain embodiments, the deformable in-feed assembly forms a telescopic structure with a hollow inner volume.

In certain embodiments, the vertical distance the parts of the deformable in-feed assembly are configured to move during the retraction and extension, depends on the size of the apparatus and the parts of the deformable in-feed assembly. In certain embodiments, the upper portion of the deformable in-feed assembly is configured to move vertically only in the vertically extended state of the deformable in-feed assembly, to allow the deformable in-feed assembly to be sealed against the reaction chamber. In certain embodiments, the upper portion of the deformable in-feed assembly is configured to move vertically 3-20 mm, preferably 5-10 mm up and/or down, in the vertically extended state of the deformable in-feed assembly. In certain embodiments, the lower portion of the deformable in-feed assembly is configured to move vertically in the vertically extended state and when the assembly is deforming between the vertically retracted and extended state. In certain embodiments, the vertical distance the lower portion of the deformable in-feed assembly is configured to move is 100-300 mm.

In certain embodiments, the apparatus comprises a pre-tensioning mechanism to pre-tension the resilient tubular conduit by preventing the resilient tubular conduit from returning to an unstretched position. In certain embodiments, the apparatus comprises a pre-tensioning mechanism around the resilient tubular conduit, configured to generate mechanical force to the resilient tubular conduit by preventing the resilient tubular conduit from returning to an unstretched/relaxed position. In certain embodiments, the pre-tensioning mechanism is around the perimeter of the resilient tubular conduit. In certain embodiments, the pre-tensioning mechanism is configured to generate pre-tension to the resilient tubular conduit continuously, the pre-tensioning mechanism continuously preventing the resilient tubular conduit from returning to an unstretched/relaxed position.

In certain embodiments, the pre-tensioning mechanism is configured to generate mechanical force to the deformable in-feed assembly via the resilient tubular conduit. In certain embodiments, the pre-tensioning mechanism is configured to generate mechanical force to the upper portion of the deformable in-feed assembly. In certain embodiments, the pre-tensioning mechanism is configured to generate mechanical force to the upper and lower portion of the deformable in-feed assembly.

In certain embodiments, the pre-tensioning mechanism is configured to adjust the position of the resilient tubular conduit. In certain embodiments, the resilient tubular conduit is configured to deform under adjustment between parts making up the pre-tensioning mechanism.

In certain embodiments, the resilient tubular conduit and the pre-tensioning mechanism are configured to stabilize and to prevent leakage of the deformable in-feed assembly by generating mechanical force to the deformable in-feed assembly. In certain embodiments the mechanical force generated by the pre-tensioning mechanism is configured to pull or retract the upper portion of the deformable in-feed assembly upwards, away from the reaction chamber, and/or in line with the vertical centre axis of the lower portion of the deformable in-feed assembly continuously, during the deformation of the deformable in-feed assembly and in the vertically extended and/or retracted state. In certain embodiments the mechanical force generated by the pre-tensioning mechanism is configured to co-centre the upper portion with the lower portion of the deformable in-feed assembly continuously, during the deformation of the deformable in-feed assembly and in the vertically extended and/or retracted state.

In certain embodiments, the resilient tubular conduit and/or the pre-tensioning mechanism is/are configured to stabilize the movement of the deformable in-feed assembly.

In certain embodiments, the resilient tubular conduit and/or the pre-tensioning mechanism is/are configured to prevent vibration and unwanted particle generation of the deformable in-feed assembly, particularly while the deformable in-feed assembly is being moved. In certain embodiments, the resilient tubular conduit and/or the pre-tensioning mechanism is/are configured to prevent vibration and unwanted particle generation of the deformable in-feed assembly also while the deformable in-feed assembly is not being moved and is, hence, essentially stationary.

In certain embodiments, the resilient tubular conduit and/or the pre-tensioning mechanism is/are configured to prevent leakage of gases containing reactant species from the deformable in-feed assembly at a joint between the upper and the lower portion. In certain embodiments, the resilient tubular conduit and/or the pre-tensioning mechanism is/are configured to prevent leakage of gases containing reactant species from the deformable in-feed assembly also at distal ends of the deformable in-feed assembly, at joints coupled to other parts of the apparatus. In certain embodiments, the pre-tensioning mechanism is configured to prevent leakage of gases containing reactant species from the deformable in-feed assembly at a joint between the upper and the lower portion. In certain embodiments, the pre-tensioning mechanism is configured to prevent leakage of the deformable in-feed assembly also at distal ends of the deformable in-feed assembly, at joints coupled to other parts of the apparatus.

In certain embodiments, the resilient tubular conduit and/or the pre-tensioning mechanism is/are configured to prevent any gases in the surrounding space or in the intermediate space from leaking into the vertically extended deformable in-feed assembly and into the reaction chamber. In certain embodiments, the resilient tubular conduit and/or the pre-tensioning mechanism is/are configured to prevent any reactants in the vertically extended deformable in-feed assembly from leaking into the surrounding space or into the intermediate space.

In certain embodiments, the pre-tensioning mechanism is fixed around the periphery of the lower edge or rim of the resilient tubular conduit, the lower edge or rim of the resilient tubular conduit being configured to stretch or compress through the pre-tensioning mechanism. In certain embodiments, the stretching or compression of the lower edge or rim of the resilient tubular conduit through the pre-tensioning mechanism is configured to be limited. In certain embodiments, the pre-tensioning mechanism is coupled to the upper edge or rim of the resilient tubular conduit rigidly. In certain embodiments, the pre-tensioning mechanism is coupled to the resilient tubular conduit indirectly, one or more parts separating the pre-tensioning mechanism and the resilient tubular conduit from each other.

In certain embodiments, the pre-tensioning mechanism is configured to be adjustable vertically and/or horizontally and/or diagonally and/or angularly. In certain embodiments, the pre-tensioning mechanism is configured to be easily accessible and adjustable.

In certain embodiments, thermal expansion does not cause significant relative movement between the components making up the pre-tensioning mechanism. In certain embodiments, the pre-tensioning mechanism is comprised of nickel-based alloy, such as AISI 304, AISI 304L, AISI 316 and AISI 316L and Inconel and/or Titanium. In certain embodiments, the pre-tensioning mechanism is comprised of a material with a similar thermal expansion coefficient as the materials of the surrounding components have.

In certain embodiments, the resilient tubular conduit is arranged in a stretched position between or within the pre-tensioning mechanism. In certain embodiments, the pre-tensioning mechanism prevents the resilient tubular conduit from being in its equilibrium, relaxed and/or unstretched state. In certain embodiments, a restoring force driving an upwards directed deformation movement of the resilient tubular conduit is configured to be blocked or prevented by the pre-tensioning mechanism during the extension and retraction movement of the deformable in-feed assembly, and while the deformable in-feed assembly is in the vertically retracted or in the extended state.

In certain embodiments, the upper portion of the deformable in-feed assembly is configured to be in contact with the pre-tensioning mechanism. In certain embodiments, the upper portion of the deformable in-feed assembly comprises a projection, such as flange-, ring-, or cylinder-shaped object, coupled to its side facing the outer, or intermediate space, configured to block or prevent the resilient tubular conduit from returning to its equilibrium, resting or unstretched state. In certain embodiments, the projection is configured to be blocked or stopped against the lower plane of the pre-tensioning mechanism. In certain embodiments, the resilient tubular conduit cannot return vertically upwards further into its unstretched state once the said projection meets the lower plane of the pre-tensioning mechanism. In certain embodiments, the projection is configured to pre-tension the resilient tubular conduit.

In certain embodiments, said projection coupled to the side of the upper portion of the deformable in-feed assembly is configured to minimize unwanted particle generation arising from contact between its surface against the pre-tensioning mechanism. In certain embodiments, the projection is made of, or is coated with, a material allowing a minimal particle generation arising from friction between its surface against the pre-tensioning mechanism. In certain embodiments, the projection is made of, or is coated with a material with a low coefficient of friction and high temperature tolerance. In certain embodiments, the material comprises fluorocarbons or a fluoropolymers such as polytetrafluoroethylene (PTFE), or Perfluoroalkoxy alkanes (PFA). In certain embodiments, the material comprises a high-performance plastic, such as Polyimide (e.g., Kapton). In certain embodiments, the material comprises thermoplastic polymers such as Polyaryletherketone, (e.g., PAEK).

In certain embodiments, the projection coupled to the side of the upper portion is configured to co-centre the upper portion with the lower portion of the deformable in-feed assembly, thereby preventing unwanted contact between the upper and lower portions of the deformable in-feed assembly. In certain embodiments, the projection coupled to the side of the upper portion is configured to co-centre the upper portion with the lower portion of the deformable in-feed assembly during the deformation of the deformable in-feed assembly and in the vertically extended and/or retracted state.

In certain embodiments, a movement of the deformable in-feed assembly is configured to diverge the upper portion from the pre-tensioning mechanism. In certain embodiments, wherein the in-feed assembly is sealed against the reaction chamber in the vertically extended state of the deformable in-feed assembly, the resilient tubular conduit is arranged in a more stretched position than in the vertically extended state of the deformable in-feed assembly wherein the in-feed assembly is not sealed against the reaction chamber. In certain embodiments, in the said position, wherein the in-feed assembly is sealed against the reaction chamber, the resilient tubular conduit is arranged in a more stretched position than during the vertically retracted state of the deformable in-feed assembly. In certain embodiments, in the said position wherein the in-feed assembly is sealed against the reaction chamber, the projection in the upper portion of the deformable in-feed assembly is pulled apart from the pre-tensioning mechanism towards the reaction chamber. This arrangement is configured to compensate for thermal expansion of the parts of the apparatus that takes place during the use of the apparatus.

In certain embodiments, in a vertically extended state of the deformable in-feed assembly, wherein the in-feed assembly is sealed against the reaction chamber and the resilient tubular conduit is further stretched, the projection coupled to the side of the upper portion of the deformable in-feed assembly is configured not to be blocked against the lower plane of the pre-tensioning mechanism. In such embodiments, the projection is configured to be apart from the lower plane of the pre-tensioning mechanism, leaving a gap in between.

In certain embodiments, the apparatus comprises a movement actuating mechanism attached to the lower portion of the deformable in-feed assembly, configured to deform the deformable in-feed assembly between the vertically extended state and the vertically retracted state. In certain embodiments, the movement actuating mechanism is configured to move the deformable in-feed assembly into the vertically retracted state, wherein the in-feed assembly is in an open position with respect to the reaction chamber. In certain embodiments, the movement actuating mechanism enables loading at least one substrate into the reaction chamber from the top side of the reaction chamber. In certain embodiments, the movement actuating mechanism also enables unloading at least one substrate from the reaction chamber from the top side of the reaction chamber. In certain embodiments, the movement actuating mechanism is configured to move the deformable in-feed assembly into the vertically extended state, wherein the in-feed assembly is in a closed position with respect to the reaction chamber, sealed against the reaction chamber.

In certain embodiments, the movement actuating mechanism is configured to reversibly change the dimensions of the deformable in-feed assembly.

In certain embodiments, the movement actuating mechanism is attached to the lower portion of the deformable in-feed assembly with a spring-loaded attachment. In certain embodiments, the movement actuating mechanism comprises at least one moving shaft coupled to the lower portion of the deformable in-feed assembly with the spring-loaded attachment. In certain embodiments, the movement actuating mechanism comprises at least two moving shafts coupled to the lower portion of the deformable in-feed assembly with the spring-loaded attachment. In certain embodiments, the number of moving shafts is two. In certain other embodiments, the number of moving shafts is three or four. In certain embodiments, the moving shaft(s) are coupled to the upper half of the lower portion of the deformable in-feed assembly. In certain embodiments, the moving shaft(s) are coupled to an upper edge or rim of the lower portion of the deformable in-feed assembly.

In certain embodiments, the movement actuating mechanism comprises at least one actuator. As used herein, an actuator is a device configured to generate motion of the apparatus through at least one moving shaft. In certain other embodiments, the movement actuating mechanism comprises at least two, three or four actuators. In certain embodiments, the movement actuating mechanism comprises a plurality of actuators. In certain embodiments, an actuator or each actuator is coupled to only one (respective) moving shaft. In certain embodiments, an actuator or each actuator is coupled to two (respective) moving shafts. In certain embodiments, all the shafts and the actuators coupled to the shafts are arranged symmetrically in respect to the periphery of the deformable in-feed line. In certain embodiments, the movement actuating mechanism comprises two actuators, each coupled to its own shaft. In certain embodiments, the movement actuating mechanism comprises one actuator coupled to two shafts.

In certain embodiments, the deformable in-feed assembly is configured to deform with a force generated by the actuator(s) and the shaft(s).

In certain embodiments, the movement actuating mechanism is also configured to deform the resilient tubular conduit coupled to the upper portion of the deformable in-feed assembly. In certain embodiments, the resilient tubular conduit is configured to deform under the mechanical force generated by the actuator(s) and the moving shaft(s). In certain embodiments, the resilient tubular conduit is configured to deform under the mechanical force generated by the moving shaft(s) reversibly pushing or pulling the in-feed assembly between the vertically extended state and the vertically retracted state. In certain embodiments, in a vertically extended state of the deformable in-feed assembly wherein the in-feed assembly is fitted against the reaction chamber, the mechanical force inflicted upon the resilient tubular conduit and upon the upper portion of the deformable in-feed assembly is configured to be greater than during the vertically extended and/or retracted state of the deformable in-feed assembly, wherein the in-feed assembly is not fitted against the reaction chamber.

In certain embodiments, the coupling of the moving shaft(s) to the upper half of the lower portion of the deformable in-feed assembly is configured to reduce vibration and stabilize the movement of the deformable in-feed assembly. In certain embodiments, the coupling of the moving shaft(s) to the plane of the upper edge or rim of the lower portion of the deformable in-feed assembly is configured to reduce vibration and stabilize the movement of the deformable in-feed assembly. In certain embodiments, the coupling of the moving shaft(s) to the lower portion, above a centre of mass of the lower portion, is configured to reduce vibration and stabilize the movement of the deformable in-feed assembly.

In certain embodiments, the moving shaft(s) is/are configured to reversibly move the deformable in-feed assembly from the vertically extended state to the vertically retracted state, allowing loading of the at least one substrate into the reaction chamber. In certain embodiments, the moving shaft(s) is/are configured to reversibly move the in-feed assembly from the vertically retracted state to the vertically extended state, allowing processing of the at least one substrate in the reaction chamber.

In certain embodiments, the apparatus comprises a plurality of moving shafts, coupled symmetrically to the periphery of the deformable in-feed assembly. In certain embodiments, the number of moving shafts is two, the two shafts being placed on opposite sides of the deformable in-feed assembly. In certain other embodiments, the number of moving shafts is three, four or more, but in each case the moving shafts are symmetrically positioned with respect to the periphery of the deformable in-feed assembly.

In certain embodiments, the spring-loaded attachment is configured to couple the movement actuating mechanism resiliently into the deformable in-feed assembly, to stabilize the movement of the deformable in-feed assembly. In certain embodiments, the spring-loaded attachment couples the lower portion of the deformable in-feed assembly and the moving shaft(s) together. In certain embodiments, the spring-loaded attachment is configured to adjust the angular and/or a vertical and/or horizontal position of the lower portion of the deformable in-feed assembly. In certain embodiments, the spring-loaded attachment facilitates a vertical adjustment of the entire deformable in-feed assembly.

In certain embodiments, the spring-loaded attachment comprises a plurality of resilient components, preferably at least three resilient components, such as three or four resilient components. In certain embodiments, the moving shaft(s) is/are coupled to the lower portion of the deformable in-feed assembly through the resilient components. In certain embodiments, each resilient component within the spring-loaded attachment is configured to resist the vertical movement of the deformable in-feed assembly to stabilize the movement of the deformable in-feed assembly. In certain embodiments, the number of moving shafts is two and the number of resilient components is three or four.

In certain embodiments, each resilient component is an elastic object configured to store mechanical potential energy. In certain embodiments, each resilient component is configured to be pre-tensioned. In certain embodiments, each resilient component is configured to be pre-tensioned between the components making up the spring-loaded attachment. In certain embodiments, each resilient component is a spring. In certain embodiments, each resilient component is configured to resist the vertical, horizontal, and diagonal movement of the deformable in-feed assembly with its internally stored mechanical potential energy, thereby stabilizing the said movement. In certain embodiments, each resilient component is configured to resist and thereby stabilize the movement of the deformable in-feed assembly into the vertically extended state with its internally stored mechanical potential energy. In certain embodiments, each resilient component is configured to resist and thereby stabilize the movement of the deformable in-feed assembly into the vertically retracted state with its internally stored mechanical energy. In certain embodiments, in the vertically extended state of the deformable in-feed assembly, each resilient component is configured to adjust the angular position of the deformable in-feed line against the reaction chamber.

In certain embodiments, the accuracy of the position adjustment of the lower portion of the deformable in-feed assembly is improved, when the distance of each resilient component within the spring-loaded attachment from the surface of the deformable in-feed assembly facing the intermediate space is increased in the horizontal plane.

In certain embodiments, in the vertically extended state of the deformable in-feed assembly a vertical gap is configured to separate the lower portion of the deformable in-feed assembly from the reaction chamber. In certain embodiments, the said gap between the lower portion of the deformable in-feed assembly and the reaction chamber is configured to be closed by the movement actuating mechanism further compressing each of the resilient components. In certain embodiments, the said gap between the lower portion of the deformable in-feed assembly and the reaction chamber is configured to be closed by the movement actuating mechanism further stretching the resilient tubular conduit.

In certain embodiments, the movement actuating mechanism is configured to press the vertically extended deformable in-feed assembly vertically further towards the reaction chamber, to be sealed against the reaction chamber, by further stretching vertically the resilient tubular conduit. In certain embodiments, the movement actuating mechanism is configured to press the vertically extended deformable in-feed assembly further towards the reaction chamber, to be sealed against the reaction chamber, by further compressing each resilient component. In certain embodiments, each resilient component is configured to resist the said further compression in the vertically extended state of the deformable in-feed assembly more than the movement of the deformable in-feed assembly into the vertically extended state. In certain embodiments, each resilient component is configured to resist the vertical movement of the deformable in-feed assembly most in the vertically extended state of the deformable in-feed assembly. In certain embodiments, the resistance of each resilient component against the further compression in the vertically extended state of the deformable in-feed assembly is configured to stabilize the movement of the deformable in-feed assembly and prevent unwanted particle generation.

In certain embodiments, the resilient tubular conduit is coupled between the lower portion of the deformable in-feed assembly and a fixed element of the apparatus. In certain embodiments, the fixed element of the apparatus is the upper portion of the deformable in-feed assembly. In such embodiments, the upper portion of the deformable in-feed assembly is a static part of the deformable in-feed assembly, fixedly attached to the apparatus. In certain embodiments, the upper portion of the deformable in-feed assembly is coupled to the inner surface of the outer chamber or to another fixed element of the apparatus with a fixed position, such as a flange which is coupled to the outer chamber. In certain embodiments, the resilient tubular conduit is directly coupled to the upper portion of the deformable in-feed assembly, or indirectly through another fixed part of the apparatus, such as the outer chamber.

In certain embodiments, the upper portion of the deformable in-feed assembly is nested inside the resilient tubular conduit. In certain embodiments, in the vertically extended state of the deformable in-feed assembly, the resilient tubular conduit surrounds the entire vertical length of the upper portion of the deformable in-feed assembly. In certain embodiments, in the vertically retracted state of the deformable in-feed assembly, the resilient tubular conduit surrounds only part of the vertical length of the upper portion of the deformable in-feed assembly, whereas part of the upper portion is nested inside the lower portion of the deformable in-feed assembly.

In certain embodiments, the resilient tubular conduit is configured adjust the position of the lower portion of the deformable in-feed assembly, and the upper portion of the deformable in-feed assembly is configured to provide said lower portion with the reactant flow. In certain embodiments, the resilient tubular conduit is configured to adjust the position of the lower portion against the upper portion of the deformable in-feed assembly, to provide a leak-tight deformable in-feed assembly.

According to a second example aspect there is provided a method, comprising:
providing a reaction chamber for processing at least one substrate, and a deformable in-feed assembly comprising an upper and a lower portion movable with respect to each other; deforming the deformable in-feed assembly to a vertically retracted state and loading a substrate into the reaction chamber;
deforming the deformable in-feed assembly to a vertically extended state and flowing reactants through a resilient tubular conduit coupled to the upper portion of the deformable in-feed assembly and therefrom through the deformable in-feed assembly towards the reaction chamber.

According to a third example aspect there is provided a method, comprising:
providing a reaction chamber for processing at least one substrate, and a deformable in-feed assembly comprising an upper and a lower portion movable with respect to each other; deforming the deformable in-feed assembly to a vertically retracted state and loading a substrate into the reaction chamber;
deforming the deformable in-feed assembly to a vertically extended state and flowing reactants through the upper portion of the deformable in-feed assembly nested inside the resilient tubular conduit, and therefrom through the lower portion of the deformable in-feed assembly towards the reaction chamber.

Different non-binding example aspects and embodiments have been illustrated in the foregoing. The above embodiments are used merely to explain selected aspects or steps that may be utilized in implementations of the present invention. Some embodiments may be presented only with reference to certain example aspects. It should be appreciated that corresponding embodiments apply to other example aspects as well. In particular, the embodiments described in the context of the first aspect are applicable to each further aspect. Any appropriate combinations of the embodiments may be formed.

### BRIEF DESCRIPTION OF THE FIGURES

The invention will now be described, by way of example only, with reference to the accompanying drawings, in which:

FIG. 1 shows a schematic cross section of certain parts of a substrate processing apparatus wherein a deformable in-feed assembly is in a vertically extended state, in accordance with certain embodiments;

FIG. 2 shows an alternative schematic cross section of certain parts of the substrate processing apparatus wherein the deformable in-feed assembly is in a vertically retracted state, in accordance with certain embodiments;

FIG. 3 shows a magnified sectional view of a resilient tubular conduit in accordance with certain embodiments;

FIG. 4 shows an alternative magnified sectional view of the resilient tubular conduit in accordance with certain embodiments;

FIG. 5 shows a schematic cross section of the deformable in-feed assembly in accordance with certain embodiments;

FIG. 6 shows an alternative schematic cross section of the deformable in-feed assembly in accordance with certain embodiments;

FIG. 7 shows another alternative schematic cross section of the deformable in-feed assembly in accordance with certain embodiments;

FIG. 8 shows an alternative schematic cross section of the deformable in-feed assembly of FIG. 5 in accordance with certain embodiments;

FIG. 9 shows an alternative schematic cross section of the deformable in-feed assembly of FIG. 6 in accordance with certain embodiments;

FIG. 10 shows an alternative schematic cross section of the deformable in-feed assembly of FIG. 7 in accordance with certain embodiments;

FIG. 11 shows an alternative schematic cross section of certain parts of the substrate processing apparatus wherein the deformable in-feed assembly is in a vertically extended state, in accordance with certain embodiments;

FIG. 12 shows an alternative schematic cross section of certain parts of the substrate processing apparatus wherein the deformable in-feed assembly is in a vertically retracted state, in accordance with certain embodiments.

### DETAILED DESCRIPTION

In the following description, Atomic Layer Deposition (ALD) technology and Atomic Layer Etching (ALE) technology are used as an example.

The basics of an ALD growth mechanism are known to a skilled person. ALD is a special chemical deposition method based on sequential introduction of at least two reactive precursor species to at least one substrate. A basic ALD deposition cycle consists of four sequential steps: pulse A, purge A, pulse B and purge B. Pulse A consists of a first precursor vapor and pulse B of another precursor vapor. Inactive gas and a vacuum pump are typically used for purging gaseous reaction by-products and the residual reactant molecules from the reaction space during purge A and purge B. A deposition sequence comprises at least one deposition cycle. Deposition cycles are repeated until the deposition sequence has produced a thin film or coating of desired thickness. Deposition cycles can also be either simpler or more complex. For example, the cycles can include three or more reactant vapor pulses separated by purging steps, or certain purge steps can be omitted. Or, as for plasma-assisted ALD, for example PEALD (plasma-enhanced atomic layer deposition), or for photon-assisted ALD one or more of the deposition steps can be assisted by providing required additional energy for surface reactions through plasma or photon in-feed, respectively. One of the reactive precursors can be substituted by energy (such as mere photons), leading to single precursor ALD processes. Accordingly, the pulse and purge sequence may be different depending on each particular case. The deposition cycles form a timed deposition sequence that is controlled by a logic unit or a microprocessor. Thin films grown by ALD are dense, pinhole free and have uniform thickness.

As for substrate processing steps, the at least one substrate is typically exposed to temporally separated precursor pulses in a reaction vessel (or chamber) to deposit material on the substrate surfaces by sequential self-saturating surface reactions. In the context of this application, the term ALD comprises all applicable ALD based techniques and any equivalent or closely related technologies, such as, for example the following ALD sub-types: MLD (Molecular Layer Deposition), plasma-assisted ALD, for example PEALD (Plasma Enhanced Atomic Layer Deposition) and photon-assisted or photon-enhanced Atomic Layer Deposition (known also as flash enhanced ALD or photo-ALD).

However, the invention is not limited to ALD technology, but it can be exploited in a wide variety of substrate processing apparatuses, for example, in chemical deposition reactors such as Chemical Vapor Deposition (CVD) reactors, or in chemical etching reactors, such as in Atomic Layer Etching (ALE) reactors.

The basics of an ALE etching mechanism are known to a skilled person. ALE is a technique in which material layers are removed from a surface using sequential reaction steps that are self-limiting. A typical ALE etching cycle comprises a modification step to form a reactive layer, and a removal step to take off only the reactive layer. The removal step may comprise using a plasma species, ions in particular, for the layer removal.

In context of ALD and ALE techniques, the self-saturating surface reaction means that the surface reactions on the reactive layer of the surface will stop and self-saturate when the surface reactive sites are entirely depleted.

In the following description, Atomic Layer Deposition (ALD) technology is used as an example.

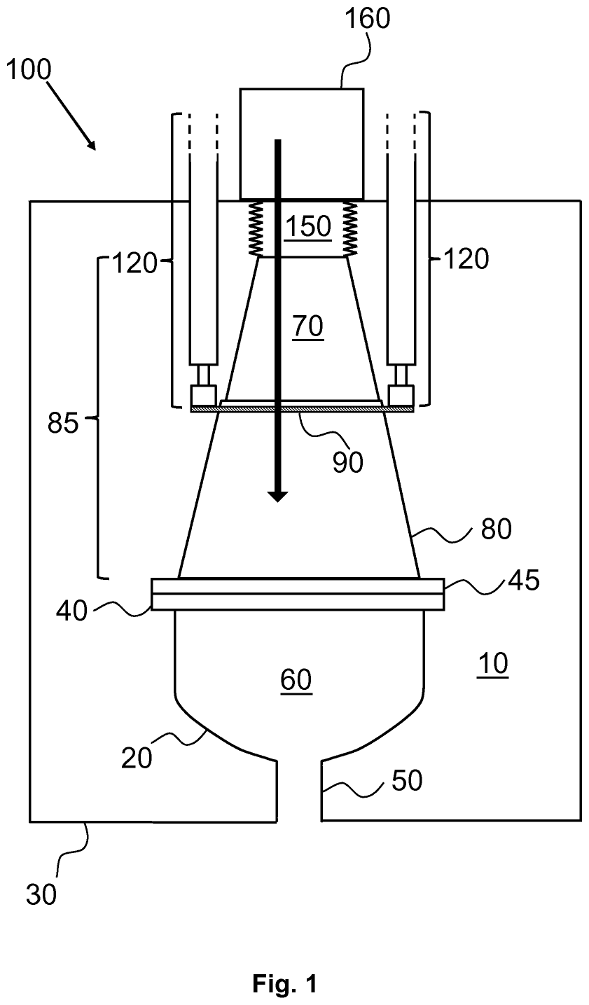

FIG. 1 shows a schematic cross section of the apparatus 100, which is a substrate processing apparatus or a reactor which is suitable, for instance, to perform plasma-enhanced ALD deposition reactions or plasma-enhanced atomic layer etching reactions.

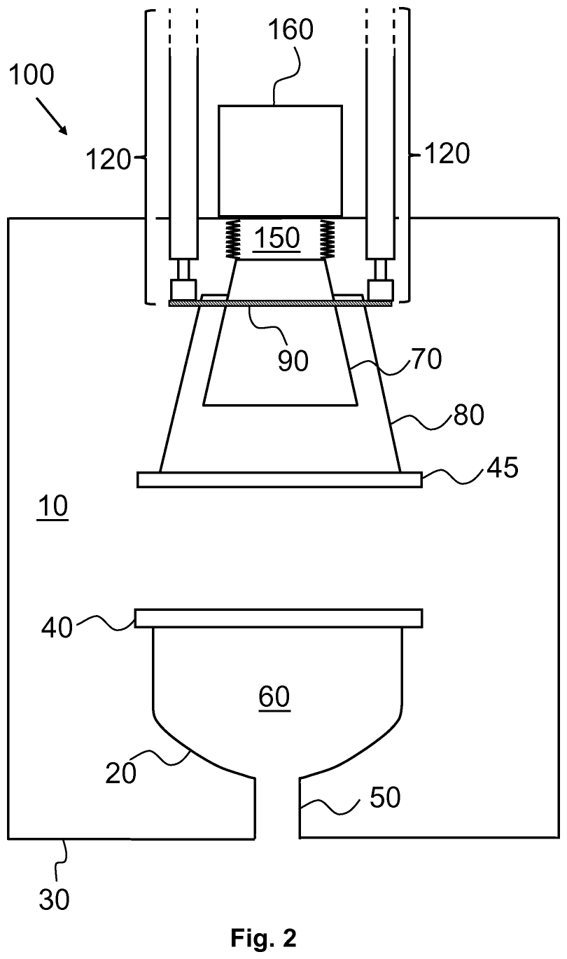

The apparatus 100 comprises a reaction chamber 20, delimiting partially a volume 60 wherein the substrate(s) are processed. The apparatus 100 further comprises a deformable in-feed assembly 85, comprising at least an upper 70 and a lower 80 portions. The deformable in-feed assembly 85 is configured to be lowered by extension and lifted up by retraction. The said upper 70 and the lower 80 portions are movable with respect to each other, the deformable in-feed assembly 85 thereby being configured to deform between a vertically extended state and a vertically retracted state. The upper 70 and the lower 80 portions have variable diameters and are configured to slide past each other during extension and retraction of the deformable in-feed assembly 85, as indicated in FIG. 2. The upper 70 and the lower 80 portions form a telescope structure.

The extension and retraction of the deformable in-feed assembly 85 is implemented by a movement actuating mechanism attached to the lower portion 80 of the deformable in-feed assembly 85. The movement actuating mechanism is configured to lift at least the said lower portion 80 up into a vertically retracted state of the deformable in-feed assembly 85, and lower at least the said lower portion 80 down into a vertically extended state of the deformable in-feed assembly 85. The movement actuating mechanism is also configured to further pull down the entire vertically extended deformable in-feed assembly 85 to be sealed against an edge of an opening in the reaction chamber 20. In certain embodiments, the deformable in-feed assembly 85 is sealed against a flange 40 surrounding an opening in the reaction chamber 20. In certain embodiments, the deformable in-feed assembly 85 is coupled to an in-feed assembly flange 45 which is sealed against the reaction chamber flange 40 in the vertically extended state of the deformable in-feed assembly 85.

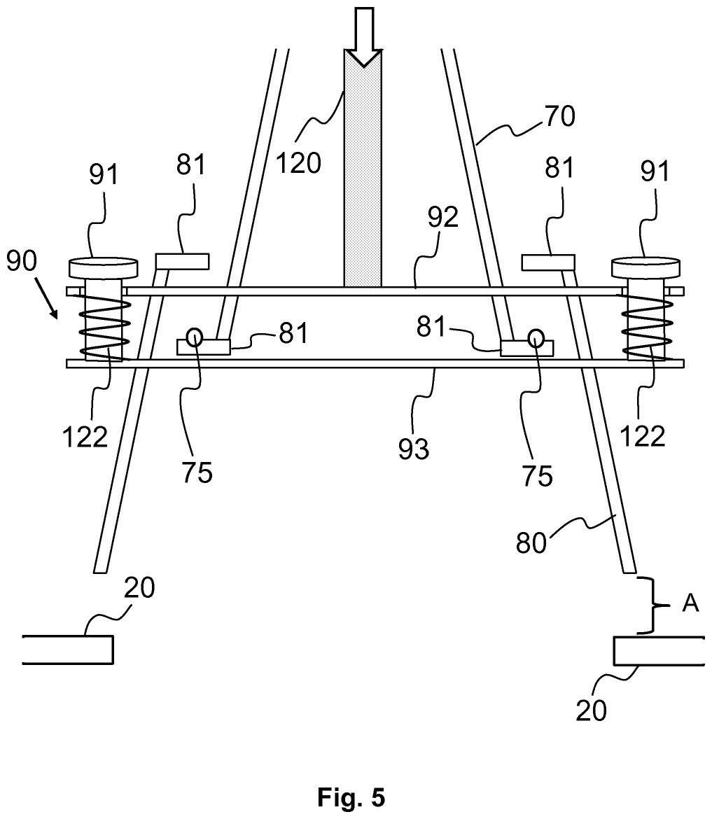

The movement actuating mechanism comprises at least one moving shaft 120 (in the FIGS. 5-10 only one is shown) coupled to the lower portion 80 of the deformable in-feed assembly 85 with a spring-loaded attachment 90, as indicated in the FIGS. 1 and 2. Preferably, the spring-loaded attachment 90 is coupled to an upper half of the lower portion 80, to allow a stable and vibration-free movement of the deformable in-feed assembly 85. Ideally, the spring-loaded attachment 90 is coupled to the upper edge or rim of the lower portion 80, to optimize the movement stability of the deformable in-feed assembly 85. In certain embodiments, wherein an adequately stable and vibration-free movement of the deformable in-feed assembly 85 is achieved with other or additional structural solutions of the apparatus 100, the spring-loaded attachment 90 can be coupled to a lower half of the lower portion 80.

As the deformable in-feed assembly 85 is lifted up in the retracted state, the substrate(s) can be loaded and/or unloaded from the side into and/or from the reaction chamber 20. The in-feed assembly 85 is lowered into the extended state and sealed against the reaction chamber 20 for substrate processing.

As used herein, the terms “up”, “down”, or “horizontal”, “vertical”, “upper” and “lower” are used to describe the directions as indicated in the figures and the directions merely aim to indicate the location and movement of parts with respect to each other. It is however possible, that the apparatus 100 is positioned in a different orientation than what is shown in the figures, and therefore the above-mentioned terms describing directions can be adjusted accordingly.

Typically, the reaction chamber 20 and the deformable in-feed assembly 85 are surrounded by an outer chamber 30, leaving an intermediate space 10 therebetween. In certain embodiments the outer chamber 30 encloses the entire reaction chamber 20 and the deformable in-feed assembly 85 within, whereas in some other embodiments only part of the reaction chamber 20 and/or the deformable in-feed assembly 85 is enclosed by the outer chamber 30. The outer chamber 30 can be a vacuum chamber wherein the pressure is kept higher than inside the reaction chamber 20 and in the deformable in-feed assembly 85, to prevent chemical leakage into the intermediate space.

The apparatus 100 comprises a resilient tubular conduit 150 coupled to the upper portion 70 of the deformable in-feed assembly 85. The upper end of the resilient tubular conduit 150 can be coupled to the inner surface of the outer chamber 30, or to another fixed element of the apparatus with a fixed position, such as a flange 153 which is coupled to the outer chamber 30. A hollow conduit is formed inside the resilient tubular conduit 150. The lower end the resilient tubular conduit 150 is coupled to the upper portion 70 of the deformable in-feed assembly 85. Reactants are fed into a first end of the hollow inner conduit of the resilient tubular conduit 150 and let out from the other end, to provide the upper portion 70 with a reactant flow. The resilient tubular conduit 150 is a resilient element, configured to generate mechanical force to at least the upper portion 70 of the deformable in-feed assembly 85 by pulling it towards itself.

A plasma source 160 is provided upstream from the resilient tubular conduit 150. The plasma source 160 comprises a plasma formation section. In certain embodiments, plasma source is 160 is located directly upstream from the resilient tubular conduit 150. In certain other embodiments, the plasma source 160 is a remote plasma source, located further upstream from the resilient tubular conduit 150. Gas phase chemicals flow through the plasma source 160 and the chemicals are activated to a plasma state. These chemical reactants, comprising the excited species generated in the plasma source 160, flow downstream through the resilient tubular conduit 150, therefrom through the vertically extended deformable in-feed assembly 85 towards the reaction chamber 20. The reactants comprising the excited species then flow to the substrate(s) residing in the volume 60 of the reaction chamber 20, generating self-saturating surface reactions on a substrate surface.

The substrate(s) to be processed can be of any form or shape, but preferably each substrate is a flat substrate such as a wafer. In some embodiments, several substrates can be processed simultaneously inside the volume 60 within the reaction chamber 20. The substrate(s) can rest inside the volume 60 on a substrate support (not shown), extending through a reaction chamber outlet 50 at the bottom of the reaction chamber 20. Alternatively, the substrate support (not shown) is connected to, or hanging from, the inner surface of the deformable in-feed assembly 85, such as the lower portion 80.

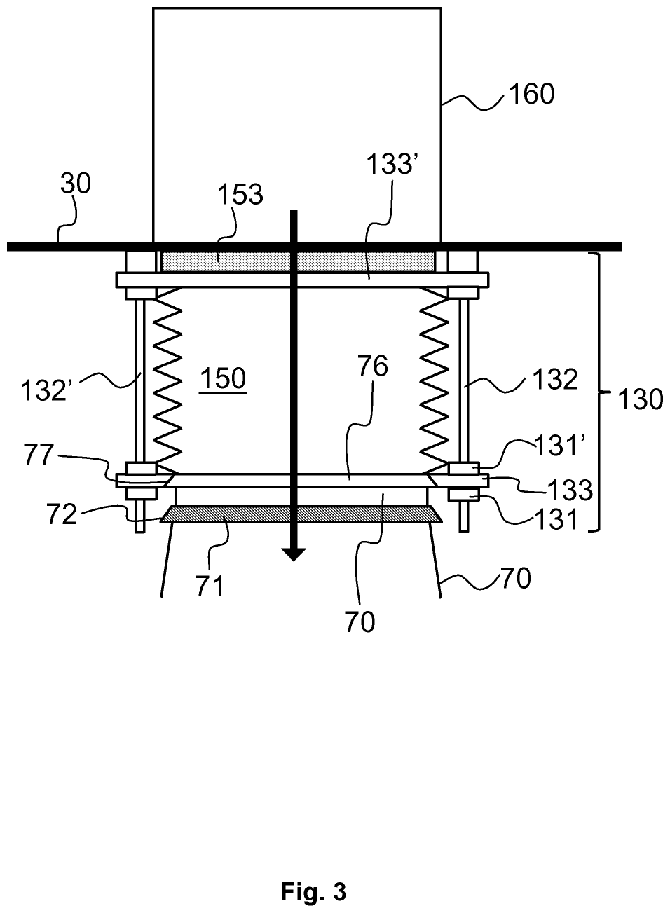

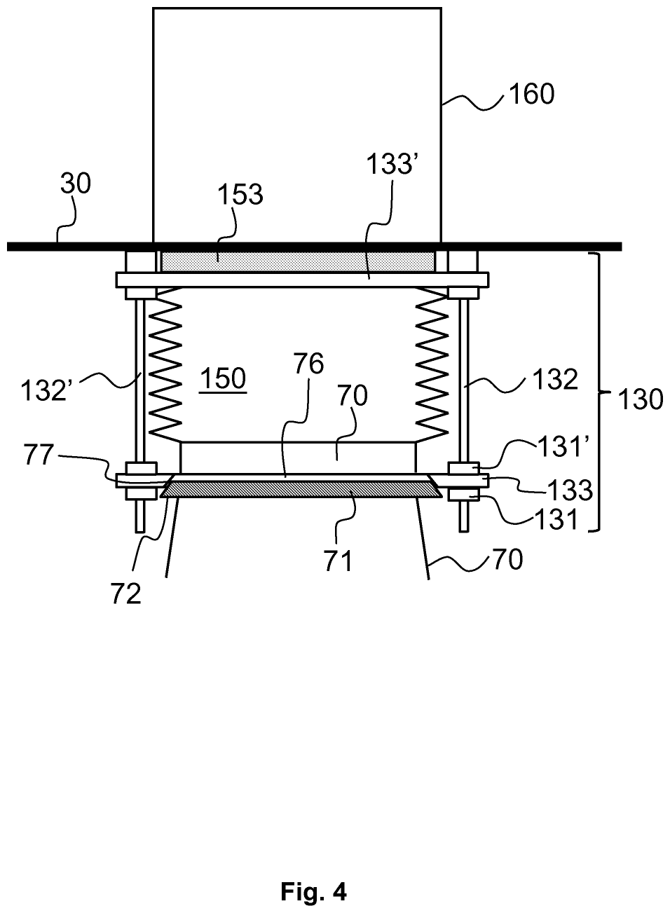

FIGS. 3 and 4 show in more detail the structure of the resilient tubular conduit 150 and the surrounding components. Around or in the periphery of the resilient tubular conduit 150 is arranged a pre-tensioning mechanism 130. The pre-tensioning mechanism 130 prevents the resilient tubular conduit 150 from returning to its unstretched position, thereby forcing the resilient tubular conduit 150 to be continuously stretched and in an unrelaxed state. The pre-tensioning mechanism 130 is thereby configured to pre-tension the resilient tubular conduit 150. The pre-tensioning mechanism 130 is configured to indirectly generate mechanical force to at least the upper portion 70 of the deformable in-feed assembly 85 via the resilient tubular conduit 150. The pre-tensioned resilient tubular conduit 150 is thereby configured to adjust and change the position of the upper portion 70 of the deformable in-feed assembly 85 by continuously pulling or retracting the upper portion 70 towards the resilient tubular conduit 150 and/or in line with the vertical center axis of the lower portion 80 of the deformable in-feed assembly 85. The mechanical force generated by the resilient tubular conduit 150 and the pre-tensioning mechanism 130 is configured to stabilize the movement of at least the upper portion 70 of the deformable in-feed assembly 85, and thereby prevent unwanted particle formation from the components of the apparatus 100. The said unwanted particles can be metal particles or non-metal particles. The said unwanted particles, when in contact with the substrate(s), can interfere with the processing of the substrate and significantly decrease the quality of the processed substrate(s).

A lower rim of the upper portion 70, and an upper rim of the lower portion 80 of the deformable in-feed assembly 85 comprise a horizontal collar 81 as indicated in FIGS. 5-10. These horizontal collars 81 of the upper 70 and lower 80 portions are configured to overlap with each other in the vertically extended state of the deformable in-feed assembly 85. As the pre-tensioned resilient tubular conduit 150 pulls the upper portion 70 upwards in the extended state of the deformable in-feed assembly 85, the upper 70 and the lower 80 portions are pressed against each other forming a sealed junction. Thereby, the resilient tubular conduit 150 and the pre-tensioning mechanism 130 are configured to allow formation of a leak-tight deformable in-feed assembly 85 in the vertically extended state of the deformable in-feed assembly 85.

The pre-tensioning mechanism 130 is coupled to an element of the apparatus 100 with a fixed position, preferably above the resilient tubular conduit 150. In certain embodiments, an upper portion 133′ of the pre-tensioning mechanism 130 is coupled to the outer chamber 30, or to the flange 153 coupled to the outer chamber 30. In certain embodiments, the upper end of the resilient tubular conduit 150 is coupled to the same fixed element, such as the flange 153, as the upper portion 133′ of the pre-tensioning mechanism 130. The pre-tensioning mechanism 130 extends downwards over the resilient tubular conduit 150, a lower portion 133 of the pre-tensioning mechanism 130 being arranged around the lower periphery or below the resilient tubular conduit 150. The upper 133′ and lower 133 portions of the pre-tensioning mechanism 130 are connected to each other by adjustable supports 132, 132′. The said adjustable supports 132, 132′ are configured to stabilize the structure of the pre-tensioning mechanism 130. The said adjustable supports 132, 132′ comprise adjustment components 131, 131′, such as nuts and/or washers, which are configured to allow adjustment of the proximity of the upper portion 133′ from the lower portion 133. Thereby the adjustable supports 132, 132′ are configured to adjust the degree of pre-tensioning of the resilient tubular conduit 150.

The lower portion 133 of the pre-tensioning mechanism 130 is arranged around the lower periphery or below the resilient tubular conduit 150 so, that the resilient tubular conduit 150 and the upper portion 70 can move and/or stretch through the lower portion 133. The lower portion 133 comprises an opening 76, through which the resilient tubular conduit 150 can move and stretch vertically and/or horizontally and/or diagonally. In certain embodiments, also part of the upper portion 70 of the deformable in-feed assembly 85 is configured to move vertically through the opening 76 in the lower portion 133 during the vertical extension and retraction of the deformable in-feed assembly 85.

The upper portion 70 of the deformable in-feed assembly 85 comprises a projection 71, such as flange-, ring-, or cylinder-shaped object, coupled to the outer perimeter surface of the said upper portion 70, configured to block the resilient tubular conduit 150 from returning to its equilibrium or unstretched state. In some other embodiments, the surface of the upper portion 70 facing the intermediate space 10 comprises several projections 71, such as pins or plugs, arranged symmetrically around the outer perimeter surface of the upper portion 70. Therefore, with the term projection 71 can be meant also a plurality of individual projections 71. The resilient tubular conduit 150 is arranged in a vertically stretched pre-tensioned position between the pre-tensioning mechanism 130 so, that the projection 71 is configured to be blocked against a lower surface of the lower portion 133 of the pre-tensioning mechanism 130, thereby preventing the resilient tubular conduit from returning to its unstretched state. The said projection 71 is configured to be blocked against the lower portion 133 of the pre-tensioning mechanism 130 during the vertical extension/retraction of the deformable in-feed assembly 85 and when the deformable in-feed assembly 85 is in the vertically retracted state as indicated in FIG. 4.

The projection 71 is configured to be blocked against the lower portion 133 of the pre-tensioning mechanism 130 also in the vertically extended state of the deformable in-feed assembly 85. As the vertically extended deformable in-feed assembly 85 is pulled further down and the resilient tubular conduit 150 is vertically further stretched so that the deformable in-feed assembly 85 can be fitted against the reaction chamber 20, the projection 71 is configured to detach from the lower portion 133 of the pre-tensioning mechanism 130. As the projection 71 detaches from the said lower portion 133, it moves further down along with the said upper portion 70 as indicated in the FIG. 3. The movement actuating mechanism is configured to move the lower portion 80 of the deformable in-feed assembly 85 between alternating positions in the vertically extended and retracted state of the said assembly 85. The movement of the lower portion 80 of the deformable in-feed assembly 85 is configured to also move the upper portion 70, and thereby detach the projection 71 from the pre-tensioning mechanism 130.

Preferably, the size of the opening 76 is adjusted to the diameter of the projection 71. In certain embodiments, the opening 76 in the lower portion 133, through which the resilient tubular conduit 150 and the upper part of the upper portion 70 can move, is oblique cut. This means, an edge 77 of the opening 76 is inclined towards the upper part of the apparatus and not orthogonal in relation to the horizontal plane of the lower portion 133 of the pre-tensioning mechanism 130. In certain embodiments, the shape of an outer edge 72 of the projection 71 is also oblique cut in relation to the horizontal plane of the projection 71, the edge 72 thereby conforming to the said oblique cut edge 77 of the opening 76. The said oblique shapes of the edge 72 of the projection 71 and the edge 77 of the opening 76 allows the projection 71 to be blocked against the lower portion 133 of the pre-tensioning mechanism 130 from below of the lower portion 133. The said oblique shapes of the edges 72 and 77 allows the projection 71 to move upwards smoothly against the lower portion 133 preventing unwanted particle formation. The unwanted particle formation in a surface-to-surface contact between the edge 72 of the projection 71, and the edge 77 of the opening 76 projection is further prevented by the selected material of the projection 71 and/or the lower portion 133 of the pre-tensioning mechanism 130. In certain embodiments, the projection 71 is made of, or is coated with a material with a low coefficient of friction and high temperature tolerance. The blocking mechanism of the projection 71 against the pre-tensioning mechanism 130 can also be arranged in any alternative manner wherein unwanted particle formation is minimized.

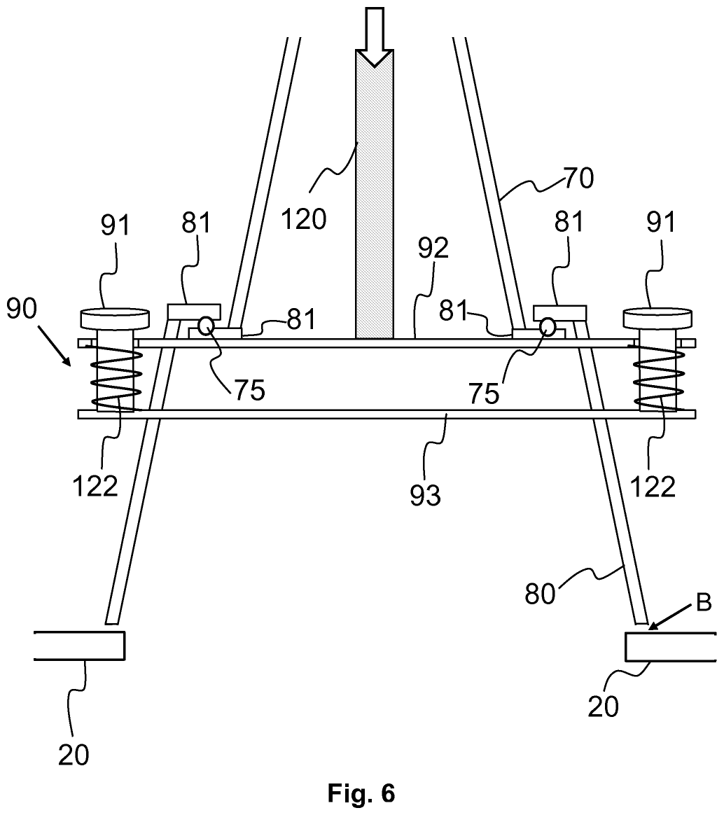

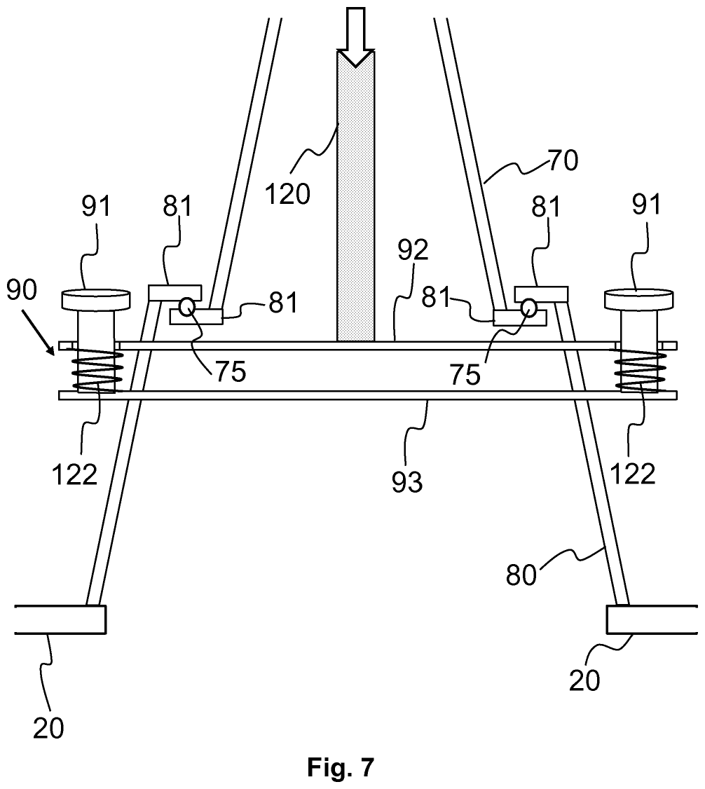

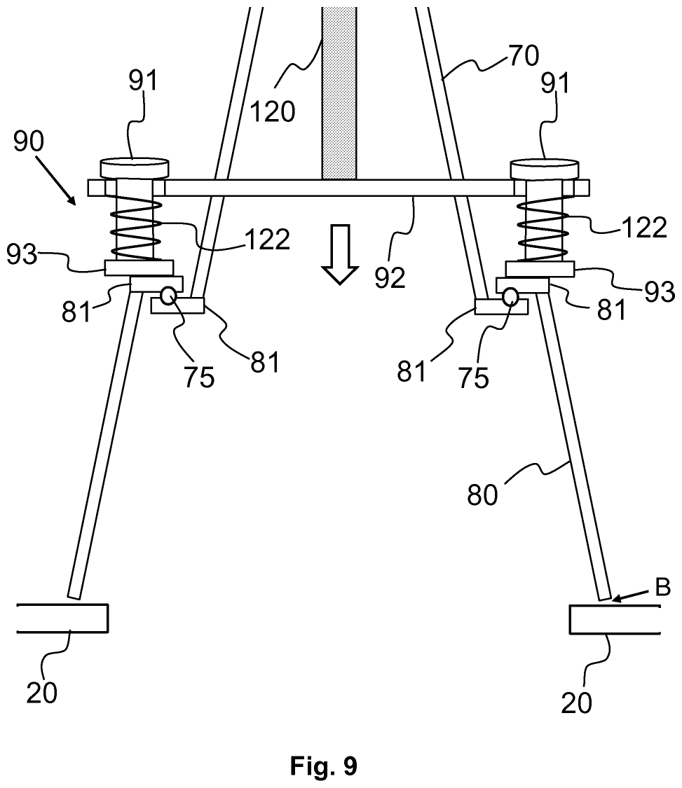

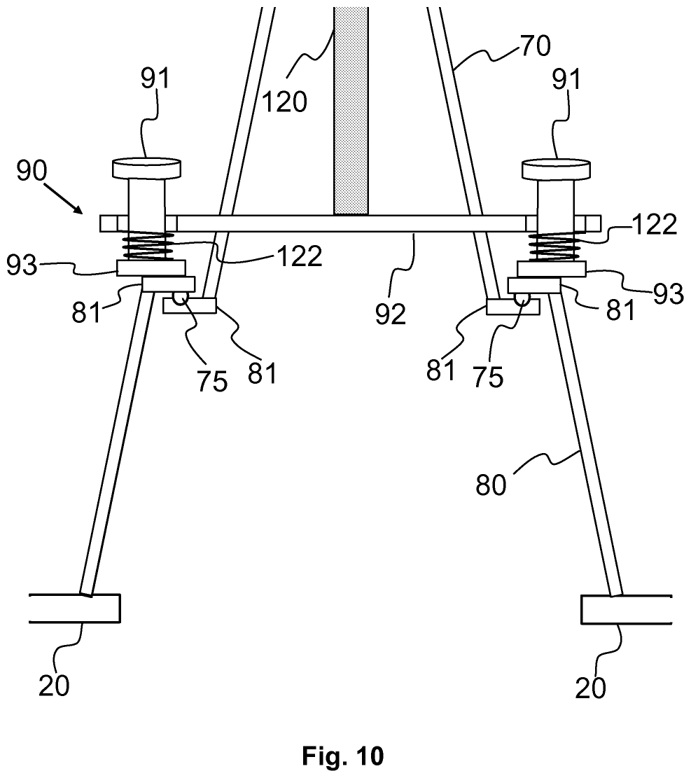

The resilient tubular conduit 150 is vertically further stretched when the deformable in-feed assembly 85 is fitted against the reaction chamber 20, as indicated in the FIGS. 7 and 10, than in the vertically extended state of the deformable in-feed assembly 85 wherein the in-feed assembly 85 is not fitted against the reaction chamber 20, as indicated in the FIGS. 6 and 9. When the deformable in-feed assembly 85 is fitted against the reaction chamber 20, the projection 71 around the upper portion 70 of the deformable in-feed assembly 85 is further pulled downwards, and the projection 71 is not pressed against the lower portion 133 of the pre-tensioning mechanism 130. When the deformable in-feed assembly 85 is fitted against the reaction chamber 20, the resilient tubular conduit 150 can be vertically, for example, 3-20 mm further stretched than in the other positions of the deformable in-feed assembly 85, and a gap of corresponding length separates the projection 71 from the lower portion 133 of the pre-tensioning mechanism 130. As the movement actuating mechanism starts lifting the lower portion 80 of the vertically extended deformable in-feed assembly 85 up with the shaft(s) 120 separating it from the reaction chamber 20, the projection eventually 71 moves along the upper portion 70 upwards until it is blocked against the lower portion 133 of the pre-tensioning mechanism 130. The resilient tubular conduit 150 cannot return to its unstretched state further, and therefore the resilient tubular conduit 150 remains pre-tensioned. The resilient tubular conduit 150 is configured to pull continuously the upper portion 70 towards itself as it tries to return to its unstretched state.

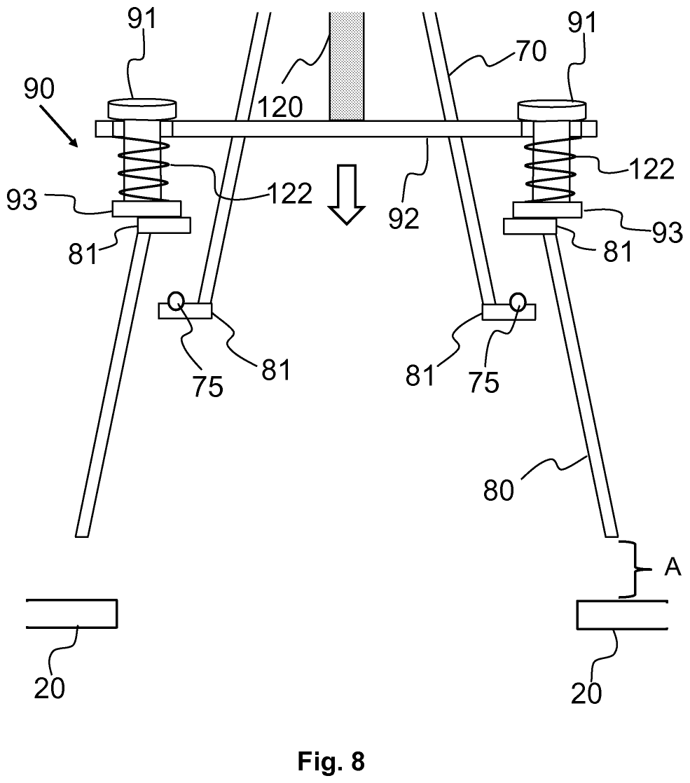

The movement actuating mechanism comprising the moving shaft(s) 120 is coupled to the lower portion 80 of the deformable in-feed assembly 85 with a spring-loaded attachment 90, as indicated in the FIGS. 1-2 and 5-10. The spring-loaded attachment 90 comprises an upper 92 and lower 93 coupling parts for coupling the shaft(s) 120 to the lower portion 80 of the deformable in-feed assembly 85. Both upper 92 and lower 93 coupling parts may be composed of more than one part. For example, the spring-loaded attachment 90 may comprise more than one lower 93 coupling part, as indicated in the exemplary embodiments of FIGS. 8-10. In another exemplary embodiment, each moving shaft 120 is coupled to its own separate individual upper coupling part 92. Regardless of the exact design of the spring-loaded attachment 90, the moving shaft(s) 120 is/are coupled to at least one upper coupling part 92, and the lower portion 80 of the deformable in-feed assembly 85 is coupled to at least one lower coupling part 93. In all the possible embodiments, the upper coupling part 92 is adjustably and movably coupled to the lower coupling part 93.

The spring-loaded attachment 90 further comprises resilient components 122 coupling the upper 92 and lower 93 coupling parts together. In certain embodiments, the resilient components 122 are positioned between the upper 92 and lower 93 coupling parts, optionally placed around connectors 91, as indicated in the FIGS. 5-10. Each resilient component 122 is resilient at least in the directions the shaft(s) 120 is/are moving the assembly 85. Each resilient component 122 is configured to store mechanical potential energy. Each resilient component 122, for example a spring, is configured to resist vertical, horizontal, and diagonal movement of the deformable in-feed assembly 85, thereby stabilizing the movement of the deformable in-feed assembly 85. Each resilient component 122 is configured to be pre-tensioned between the upper 92 and lower 93 coupling parts.

In certain embodiments the upper 92 and/or lower 93 coupling parts are further coupled together with the connectors 91, each connector 91 being coupled to a resilient component 122. The connectors 91 are configured to support and stabilize the movement of the deformable in-feed assembly 85. In certain embodiments, each connector 91 is adaptably and movably coupled to the upper coupling part 92 only. For example, each connector 91 has a fixed attachment point in the lower 93 coupling part, whereas the upper coupling part 92 is arranged movably around the periphery of the connector 91. The connectors 91 can be shaped to form a fastener type structure, to prevent the upper coupling part 92 from disengaging with the connectors 91 but still allowing the upper coupling part 92 to move along at least a vertical plane of the connectors 91. The said vertical movement of the upper coupling part 92 along the vertical plane of the connectors 91 is restricted by the resilient component(s) 122. The vertical position of the upper coupling part 92 in respect to the connectors 91 is dependent on the vertical position of the deformable in-feed assembly 85. All the connectors 91 are distributed symmetrically in the periphery of the deformable in-feed assembly 85 in respect of all the moving shafts 120.

In certain embodiments, each moving shaft 120 is coupled via the upper coupling part 92 to at least two connectors 91 and/or to at least two resilient components 122. In certain embodiments, the number of connectors 91 and/or resilient components 122 coupled to each moving shaft 120 is three or four. In certain embodiments, the moving shaft(s) 120 is/are coupled to at least three, preferably four connectors 91 and/or at least three, preferably four resilient components 122 of the apparatus through a single upper coupling part 92.

In a vertically retracted state of the deformable in-feed assembly 85, as indicated in the alternative embodiments of the FIGS. 5 and 8, the moving shaft(s) 120, the spring-loaded attachment 90 and the lower portion 80 are lifted in an upper position. In the vertically retracted state of the deformable in-feed assembly 85, as the lower portion 80 is lifted up, the upper portion 70 is at least partially nesting inside the lower portion 80, leaving a gap A between the lower edge of the lower portion 80 and the reaction chamber 20. The gap A allows the inner volume 60 of the reaction chamber 20 to be accessed and the substrate(s) to be loaded and/or unloaded into/from the reaction chamber 20. In the vertically retracted state of the deformable in-feed assembly 85, each resilient component 122 is pre-tensioned between the upper 92 and lower 93 coupling parts. The parts of the apparatus shown in detail in the alternative embodiments of the FIGS. 5 and 8 represent the embodiment shown in the FIG. 2.

The movement actuating mechanism is configured to move with the moving shaft(s) 120 the lower portion 80 towards the reaction chamber 20 and into the vertically extended state of the deformable in-feed assembly 85. During the said movement towards the reaction chamber 20, the moving shaft(s) 120 is/are configured to push the upper coupling part 92, and thereby the other parts of the spring-loaded attachment 90 and the lower portion 80 towards the reaction chamber 20. The upper coupling part 92 is configured to press against the resilient components 122 during the said movement, and the resilient components 122 are configured to resist the compression thereby stabilizing the said movement. The upper coupling part 92 is configured to press against the resilient components 122, and the resilient component is configured to resist the pressure inflicted upon it with unchanged force until the in-feed assembly 85 is in a vertically extended state.

In the vertically extended state of the deformable in-feed assembly 85, the deformable in-feed assembly 85 is fully extended. The horizontal collars 81 in the rims of the upper 70 and lower 80 portions overlap each other and form a sealed deformable in-feed assembly 85, as indicated in the alternative embodiments of the FIGS. 6 and 9. A seal 75 between the upper 70 and lower 80 portion further seals the interface and prevents unwanted contact between the said portions of the deformable in-feed assembly 85. The seal 75 can be provided at the lower rim and/or above the horizontal collar of the upper portion 70 of the deformable in-feed assembly 85. The seal 75 can also be provided at the upper rim and/or below the horizontal collar of the lower portion 80 of the deformable in-feed assembly 85. In certain embodiments, the seal 75 is an o-ring seal and it can have a rounded or an angular profile. In any case, the seal 75 has a shape and form which does not promote particle adherence and allows it to be kept clean. The seal 75 is made of material which minimizes generation of unwanted particles during the operation of the apparatus. The seal 75 can be a metallic or a non-metallic seal.

Once the movement actuating mechanism has moved the deformable in-feed assembly 85 in the vertically extended state, a small gap B is still left between the lower edge of the lower portion 80 and the reaction chamber 20, as indicated in the FIGS. 6 and 9. The gap B is configured to be closed by the movement actuating mechanism pressing the lower portion 80 of the deformable in-feed assembly 85 against the surface of the reaction chamber 20 prior to substrate processing. The gap B is configured to be closed by the movement actuating mechanism, by further pressing the upper coupling part 92 towards the reaction chamber 20, thereby compressing each of the resilient components 122 even more than during the movement to the vertically extended state. This is indicated in the alternative embodiments of the FIGS. 7 and 10. The said further compressed resilient components 122 are configured to resist the movement of the deformable in-feed assembly 85 even more than the movement to the vertically extended state. This further stabilizes the movement of the deformable in-feed assembly 85 and prevents unwanted particle formation.

Vertical stretching of the resilient tubular conduit 150 further towards the reaction chamber 20 also contributes towards closing the gap B. The movement actuating mechanism pushing the deformable in-feed assembly 85 further towards the reaction chamber 20 is configured to detach the projection 71 from the lower portion 133 of the pre-tensioning mechanism 130 and move the projection 71 along with the upper portion 70 further downwards as indicated in the FIG. 3. A movement of the lower portion 80 of the deformable in-feed assembly 85 is therefore configured to diverge the upper portion 70 from the pre-tensioning mechanism 130. The said further vertical stretching of the resilient tubular conduit 150 is configured to stabilize and/or prevent leakage of the deformable in-feed assembly 150. The parts of the apparatus shown in detail in FIG. 3 and in the alternative embodiments of the FIGS. 7 and 10 represent the embodiment shown in the FIG. 1.

Therefore, the width of the gap B between the lower portion 80 of the deformable in-feed assembly 85 and the reaction chamber 20, is configured to approximately correspond to the length the resilient tubular conduit 150 must be further stretched in the vertically extended position of the deformable in-feed assembly 85, for the lower portion 80 of the deformable in-feed assembly 85 to close against the reaction chamber 20. In certain embodiments, the apparatus is configured to close the gap B with the said mechanism, to compensate for a relative movement between components of the apparatus 100 caused by thermal expansion, and for inaccurate positioning of the components of the apparatus.

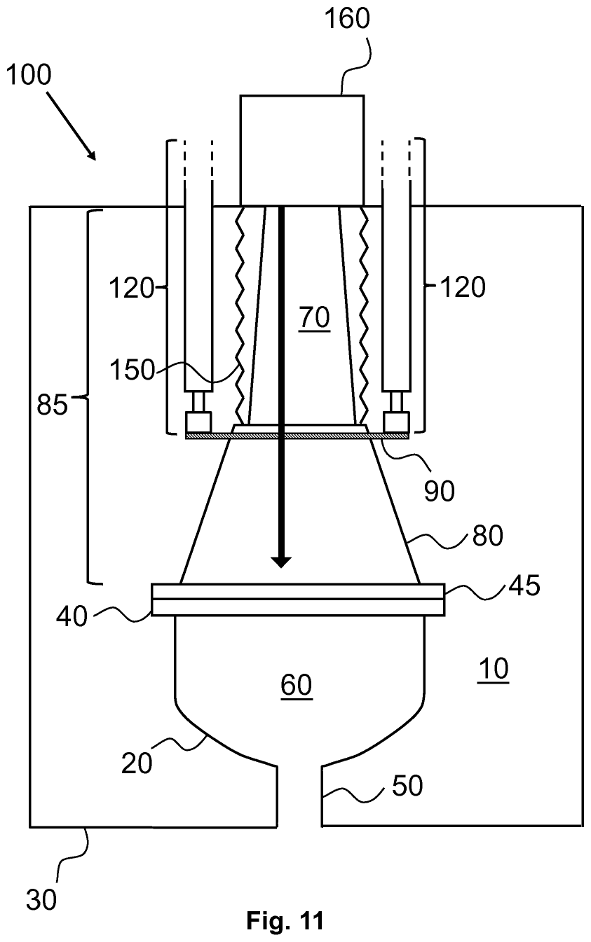

FIG. 11 shows a schematic cross section of the apparatus 100 according to another embodiment, wherein the deformable in-feed assembly 85 is in the vertically extended state, configured to provide the reaction chamber 20 with the reactant flow. According to this embodiment, the upper portion 70 of the deformable in-feed assembly 85 is a static component of the apparatus and positioned at least partly inside the resilient tubular conduit 150. In the conformation of FIG. 11, the upper portion 70 of the deformable in-feed assembly 85 is coupled between the lower portion 80 of the deformable in-feed assembly 85 and a fixed element of the apparatus, such as the outer chamber 30. A top part of the resilient tubular conduit 150 is coupled to a fixed element of the apparatus, such as the upper portion 70 of the deformable in-feed assembly 85 and/or the outer chamber 30, whereas a bottom part of the resilient tubular conduit 150 is coupled to the lower portion 80 of the deformable in-feed assembly 85. The top part of the resilient tubular conduit 150 may be coupled directly or indirectly to the upper portion 70. In the vertically extended state of the deformable in-feed assembly 85, the resilient tubular conduit 150 is vertically stretched and surrounds the upper portion 70 of the deformable in-feed assembly 85 from its entire (or majority of) vertical length. The resilient tubular conduit 150 is vertically stretched enough to allow the lower portion 80 of the deformable in-feed assembly 85 to be lowered and sealed against the edge of an opening in the reaction chamber 20. In such embodiment, the resilient tubular conduit 150 must possess specific qualities enabling the required resiliency/travel length and rigidity. In an embodiment, the material of the resilient tubular conduit 150 comprises fluorocarbons or fluoropolymers such as polytetrafluoroethylene (PTFE), and/or the resilient tubular conduit 150 is a PTFE bellows. The resilient tubular conduit 150 is vertically stretched enough also to allow an upper edge of the lower portion 80 to be lowered and sealed against a lower edge of the upper portion 70, thereby providing a leak-tight interface between the portions 70, 80 in the vertically extended state of the deformable in-feed assembly 85.

The configuration of FIG. 11 of the apparatus allows the reactants to flow from the plasma source 160 directly into the upper portion 70 of the deformable in-feed assembly 85, and therefrom into the lower portion 80 of the deformable in-feed assembly 85 and towards the reaction chamber 20. Consequently, the resilient tubular conduit 150 does not participate directly in flowing reactants into the deformable in-feed assembly 85 in such configuration. Accordingly, the resilient tubular conduit 150 is in this case configured to stabilize and adjust the position of the lower portion 80 of the deformable in-feed assembly 85 only, whereas the upper portion 70 is configured to be in a fixed position. Moreover, the resilient tubular conduit 150 is configured to generate mechanical force only to the lower portion 80 of the deformable in-feed assembly 85 with its internally stored mechanical potential energy.

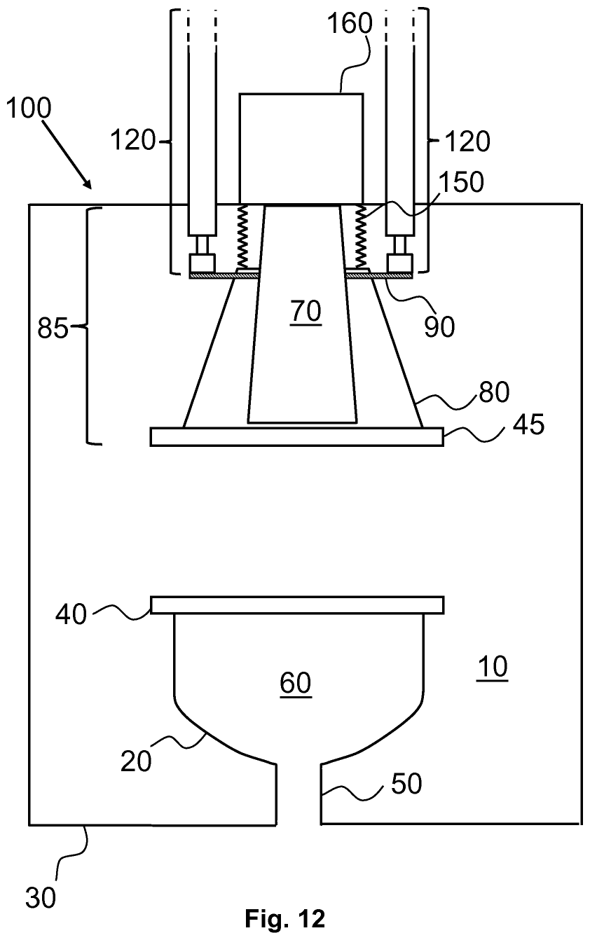

FIG. 12 shows a configuration of the apparatus 100 presented in the FIG. 11, wherein the deformable in-feed assembly 85 is in the vertically retracted state, i.e., the deformable in-feed assembly 85 is open and allowing substrate loading. The apparatus 100, according to embodiments presented in FIGS. 11 and 12, is configured to lift the lower portion 80 of the deformable in-feed assembly 85 with the movement actuating mechanism attached to the lower portion 80, thereby also compressing the resilient tubular conduit 150 to its compressed and/or unstretched position. The lower portion 80 is configured to slide at least partly over the upper portion 70 of the deformable in-feed assembly 85. In an embodiment, the apparatus according to the FIGS. 11 and 12 does not comprise a pre-tensioning mechanism 130 for the resilient tubular conduit 150. The structure of the apparatus according to the FIGS. 11 and 12 is beneficial, as the simplified in-feed assembly structure is easier to install as it may comprise fewer parts and the need for position accuracy and angle adjustment of the upper portion 70 is avoided. Moreover, the fixed position of the upper portion 70 improves the leak-tightness of the entire deformable in-feed assembly 85.

Without limiting the scope and interpretation of the patent claims, certain technical effects of one or more of the example embodiments disclosed herein are listed in the following. A technical effect is prevention of unwanted particle generation from the parts of the apparatus. A further technical effect is stabilizing the movement of the deformable in-feed assembly upon retraction and extension of the deformable in-feed assembly. A further technical effect is stabilizing the structure of the deformable in-feed assembly while it is being essentially stationary. A further technical effect is preventing leakage from the vertically extended deformable in-feed assembly.

The foregoing description has provided by way of non-limiting examples of particular implementations and embodiments of the invention a full and informative description of the best mode presently contemplated by the inventors for carrying out the invention. It is however clear to a person skilled in the art that the invention is not restricted to details of the embodiments presented above, but that it can be implemented in other embodiments using equivalent means without deviating from the characteristics of the invention.

Furthermore, some of the features of the above-disclosed embodiments of this invention may be used to advantage without the corresponding use of other features. As such, the foregoing description should be considered as merely illustrative of the principles of the present invention, and not in limitation thereof. Hence, the scope of the invention is only restricted by the appended patent claims.

1. A substrate processing apparatus, comprising:
a reaction chamber for processing at least one substrate;
a deformable in-feed assembly comprising an upper and a lower portion movable with respect to each other, the deformable in-feed assembly being configured to deform between a vertically extended state facilitating a reactant flow towards the reaction chamber, and a vertically retracted state allowing substrate loading; and
a resilient tubular conduit coupled to the upper portion of the deformable in-feed assembly.

2. The apparatus of claim 1, wherein the resilient tubular conduit is configured to provide the deformable in-feed assembly with the reactant flow.

3. The apparatus of claim 1, wherein the resilient tubular conduit is coupled between the upper portion of the deformable in-feed assembly and a fixed element of the apparatus.

4. The apparatus of claim 1, wherein the resilient tubular conduit is configured to generate mechanical force to the deformable in-feed assembly with its internally stored mechanical potential energy.

5. The apparatus of claim 1, wherein the resilient tubular conduit is configured to stabilize and adjust the position of the upper portion of the deformable in-feed assembly (85) by generating mechanical force to the deformable in-feed assembly.

6. The apparatus of claim 1, wherein the resilient tubular conduit is configured to stretch or compress under mechanical force generated by the deformable in-feed assembly.

7. The apparatus of claim 1, wherein the lower portion of the deformable in-feed assembly is configured to be sealed against the reaction chamber in the vertically extended state of the deformable in-feed assembly to provide the reaction chamber with the reactant flow.

8. The apparatus of claim 1, comprising a sealed interface between the lower portion and the upper portion of the deformable in-feed assembly in the vertically extended state of the deformable in-feed assembly.

9. The apparatus of claim 1, wherein the portions of the deformable in-feed assembly are configured to nest inside each other in the vertically retracted state of the deformable in-feed assembly.

10. The apparatus of claim 1, comprising a pre-tensioning mechanism to pre-tension the resilient tubular conduit by preventing the resilient tubular conduit from returning to an unstretched position.

11. The apparatus of claim 10, wherein the pre-tensioning mechanism is configured to generate mechanical force to the deformable in-feed assembly via the resilient tubular conduit.

12. The apparatus of claim 10, wherein the resilient tubular conduit and the pre-tensioning mechanism are configured to stabilize and to prevent leakage of the deformable in-feed assembly by generating mechanical force to the deformable in-feed assembly.

13. The apparatus of a claim 1, comprising a movement actuating mechanism attached to the lower portion of the deformable in-feed assembly, configured to deform the deformable in-feed assembly between the vertically extended state and the vertically retracted state.

14. The apparatus of claim 13, wherein the movement actuating mechanism is attached to the lower portion (80) of the deformable in-feed assembly with a spring-loaded attachment.

15. The apparatus of claim 14, wherein the movement actuating mechanism comprises at least one moving shaft coupled to the lower portion of the deformable in-feed assembly with the spring-loaded attachment.

16. The apparatus of claim 1, wherein the resilient tubular conduit is coupled between the lower portion of the deformable in-feed assembly and a fixed element of the apparatus.

17. The apparatus of claim 16, wherein the fixed element of the apparatus is the upper portion of the deformable in-feed assembly.

18. A method, comprising:
providing a reaction chamber for processing at least one substrate, and a deformable in-feed assembly comprising an upper and a lower portion movable with respect to each other;
deforming the deformable in-feed assembly to a vertically retracted state and loading a substrate into the reaction chamber;
deforming the deformable in-feed assembly to a vertically extended state and flowing reactants through a resilient tubular conduit coupled to the upper portion of the deformable in-feed assembly and therefrom through the deformable in-feed assembly towards the reaction chamber.

19. A method, comprising:
providing a reaction chamber for processing at least one substrate, and a deformable in-feed assembly comprising an upper and a lower portion movable with respect to each other;
deforming the deformable in-feed assembly to a vertically retracted state and loading a substrate into the reaction chamber;
deforming the deformable in-feed assembly to a vertically extended state and flowing reactants through the upper portion of the deformable in-feed assembly nested inside the resilient tubular conduit, and therefrom through the lower portion of the deformable in-feed assembly towards the reaction chamber.

20. The apparatus of claim 11, wherein the resilient tubular conduit and the pre-tensioning mechanism are configured to stabilize and to prevent leakage of the deformable in-feed assembly by generating mechanical force to the deformable in-feed assembly.
